(19) United States
(12) Patent Application Publication
(10) Pub. No.: US 2018/0182912 A1
(43) Pub. Date: Jun. 28, 2018

(54) COMPOUND SEMICONDUCTOR SOLAR CELL

(71) Applicant: LG Electronics Inc., Seoul (KR)

(72) Inventors: Wonseok CHOI, Seoul (KR); Jinhee PARK, Seoul (KR); Soohyun KIM, Seoul (KR); Wonki YOON, Seoul (KR); Heonmin LEE, Seoul (KR)

(21) Appl. No.: 15/853,237

(22) Filed: Dec. 22, 2017

(30) Foreign Application Priority Data
Dec. 28, 2016 (KR) 10-2016-0181161

(51) Int. Cl. H01L 31/0735; H01L 31/0304; H01L 31/0216; H01L 31/0725

(52) U.S. Cl. CPC H01L 31/0735; H01L 31/0725; H01L 31/02168; H01L 31/03046

(57) ABSTRACT

A compound semiconductor solar cell that includes: a light absorbing layer; a first electrode; and a second electrode, wherein the light absorbing layer includes; a first semiconductor layer having a first band gap, a second semiconductor layer having a second band gap being larger than the first band gap and forming a hetero junction with the first semiconductor layer, and including a first material and a second material, and wherein in the junction buffer layer, a concentration of the first material on a surface in contact with the second semiconductor layer is larger than the concentration of the first material on a surface in contact with the first semiconductor layer, and a concentration of the second material on the surface in contact with the second semiconductor layer is smaller than the concentration of the second material on the surface in contact with the first semiconductor layer is disclosed.

### CROSS-REFERENCE TO RELATED APPLICATION

This application claims priority to and the benefit of Korean Patent Application No. 10-2016-0181161, which was filed in the Korean Intellectual Property Office on Dec. 28, 2016, the entire contents of which are incorporated herein by reference.

### TECHNICAL FIELD

The present application generally relates to a compound semiconductor solar cell.

### BACKGROUND

A compound semiconductor is not made of a single element such as silicon (Si) and germanium (Ge) and is formed by a combination of two or more kinds of elements to operate as a semiconductor. Various kinds of compound semiconductors have been currently developed and used in various fields. The compound semiconductors are typically used for a light emitting element, such as a light emitting diode and a laser diode, and a compound semiconductor solar cell using a photoelectric conversion effect, a thermoelectric conversion element using a Peltier effect, and the like.

A compound semiconductor solar cell uses a compound semiconductor in a light absorbing layer that absorbs solar light and generates electron-hole pairs. The light absorbing layer is formed using a III-V compound semiconductor such as gallium arsenide (GaAs), indium phosphide (InP), GaAlAs, gallium indium arsenide (GaInAs) and gallium indium phosphide (GaInP), a II-VI compound semiconductor such as cadmium sulfide (CdS), cadmium telluride (CdTe), and zinc sulfide (ZnS), a compound semiconductor such as CuInSe₂.

A plurality of compound semiconductor solar cells each having the above-described configuration is connected in series or in parallel to configure a compound semiconductor solar cell module.

A conventional compound semiconductor solar cell including a light absorbing layer composed of a III-V group compound semiconductor has a light absorbing layer, a first electrode located on a light incident surface of the light absorbing layer, a second electrode located on a rear surface of the light absorbing layer, and the conventional compound semiconductor solar cell has a homojunction structure in which a p-type semiconductor layer and an n-type semiconductor layer constituting the light absorbing layer are formed of the same material. Therefore, the conventional compound semiconductor solar cells have limitations in improving the efficiency.

Therefore, studies for applying a heterojunction structure in which the p-type semiconductor layer and the n-type semiconductor layer are formed of different materials to a compound semiconductor solar cell are actively under study. The compound semiconductor solar cell having the heterojunction structure can improve the efficiency as compared with the compound semiconductor solar cell of the homojunction structure by forming the band gaps of the p-type semiconductor layer and the n-type semiconductor layer to be different from each other. However, up to now, a compound semiconductor solar cell having an effective heterojunction structure has not been developed yet.

### SUMMARY

In general, one innovative aspect of the subject matter described in this specification can be implemented in a compound semiconductor solar cell comprising: a first light absorbing layer that includes GaInP; a first electrode positioned on a first surface of the first light absorbing layer; and a second electrode positioned on a second surface of the first light absorbing layer, wherein the first light absorbing layer includes; a first semiconductor layer that includes GaInP, that is doped as a first conductive type, and that has a first band gap, a second semiconductor layer that includes aluminum gallium indium phosphide (AlGaInP), that is doped as a second conductive type, that has a second band gap that is larger than the first band gap, and that forms a hetero junction with the first semiconductor layer, and a junction buffer layer positioned between the first semiconductor layer and the second semiconductor layer and that includes a first material comprising aluminum and a second material comprising gallium, and wherein in the junction buffer layer, a concentration of the first material on a surface in contact with the second semiconductor layer is larger than the concentration of the first material on a surface in contact with the first semiconductor layer, and a concentration of the second material on the surface in contact with the second semiconductor layer is smaller than the concentration of the second material on the surface in contact with the first semiconductor layer.

The foregoing and other implementations can each optionally include one or more of the following features, alone or in combination. In particular, one implementation includes all the following features in combination. A sum of a concentration of the first material in the junction buffer layer and a concentration of the second material in the junction buffer layer is between 24 and 25 atomic %. A concentration of the first material in the junction buffer layer and a concentration of the second material in the junction buffer layer are changed linearly, nonlinearly, exponentially, logarithmically or stepwise between a first surface of the junction buffer layer positioned on the first semiconductor layer and a second surface of the junction buffer layer positioned on the second semiconductor layer. A concentration of gallium in the first semiconductor layer is between 24 and 25 atomic %, a concentration of indium in the first semiconductor layer is between 25 and 26 atomic %, and a concentration of phosphide in the first semiconductor layer is 50 atomic %, and wherein a concentration of aluminum in the second semiconductor layer is between 1 and 25 atomic %, a concentration of gallium in the second semiconductor layer is between 1 and 25 atomic %, a concentration of indium in the second semiconductor layer is between 25 and 26 atomic %, and a concentration of phosphide in the second semiconductor layer is 50 atomic %. A thickness of the first semiconductor layer is between 100 and 2000 nm, a thickness of the second semiconductor layer is between 10 and 1000 nm, and a thickness of the junction buffer layer is between 10 and 300 nm. The junction buffer layer is doped as the first conductive type, and wherein (i) the first conductive type is a p-type and the second conductive type is an n-type or (ii) the first conductive type is an n-type and the second conductive type is a p-type. The junction buffer layer is doped as the first conductive type, and wherein a doping concentration of the junction buffer layer is (i) larger than a doping concentration of the first semiconductor layer and (ii) smaller than a doping concentration of the second semiconductor layer. A doping concentration of the junction buffer layer is even from a first surface of the junction buffer layer positioned on the first semiconductor layer to a second surface of the junction buffer layer positioned on the second semiconductor layer, and wherein a doping concentration of the junction buffer layer increases from the first surface of the junction buffer layer to the second surface of the junction buffer layer. The compound semiconductor solar cell of claim 1, further includes: a first window layer positioned on the first surface of the first light absorbing layer; a first contact layer positioned between the first window layer and the first electrode; an anti-reflection film that covers at least a portion of the first window layer; a first back surface field layer positioned on the second surface of the first light absorbing layer; and a second contact layer positioned between the first back surface field layer and the second electrode. The first window layer directly contacts at least a portion of the first semiconductor layer and the first back surface field layer directly contacts at least a portion of the second semiconductor layer or the first window layer directly contacts at least a portion of the second semiconductor layer and the first back surface field layer directly contacts at least a portion of the first semiconductor layer, and wherein the first window layer and the first back surface field layer include aluminum indium phosphide (AlInP). The first back surface field layer directly contacts the second semiconductor layer, and wherein the first back surface field layer is doped as the second type. The first back surface field layer directly contacts the first semiconductor layer, and wherein the first back surface field layer is doped as the first type. The compound semiconductor solar cell further includes: a second light absorbing layer that includes GaAs and positioned between the first back surface field layer and the second contact layer. The second light absorbing layer includes: a third semiconductor layer that is doped as the first type, and a fourth semiconductor layer that is doped as the second type. The third semiconductor layer and the fourth semiconductor layer form a homojunction or a heterojunction. The compound semiconductor solar cell further includes: a tunnel junction layer positioned between the first back surface field layer and the second light absorbing layer. The compound semiconductor solar cell further includes: a second window layer positioned between the tunnel junction layer and the second light absorbing layer; and a second back surface field layer positioned on a surface of the second light absorbing layer, wherein the second back surface field layer directly contacts the second contact layer. The second back surface field layer directly contacts the third semiconductor layer and is doped as the first conductive type, or wherein the second back surface field layer directly contacts the fourth semiconductor layer and is doped as the second conductive type. The first surface of the first light absorbing layer is a surface on which light is incident, and wherein the second surface of the first light absorbing layer is different from the first surface of the first light absorbing layer. The first conductive type is an n-type and the second conductive type is a p-type, or wherein the first type is a p-type and the second type is an n-type.

The subject matter described in this specification can be implemented in particular examples so as to realize one or more of the following advantages. A compound semiconductor solar cell has an improved open-circuit voltage (Voc) because a band gap of a first semiconductor layer of the compound semiconductor solar cell is smaller than a band gap of a second semiconductor layer of the compound semiconductor solar cell.

In addition, a junction buffer layer of the compound semiconductor solar cell, which is coupled between the first semiconductor layer including a first material, e.g., GaInP, and the second semiconductor layer including a second material, e.g., AlGaInP, is doped with suitable materials at suitable concentrations such that the band spike can be reduced or eliminated. Thus, even if the difference between the band gaps of the first semiconductor layer and the second semiconductor layer causes the bank spike, the compound semiconductor solar cell can prevent the band spike.

Moreover, the compound semiconductor solar cell can include gallium indium phosphide (GaInP) can have higher efficiency than a compound semiconductor solar cell including gallium arsenide (GaAs) when the compound semiconductor solar cell is located at low illuminance and a room temperature.

The details of one or more examples of the subject matter described in this specification are set forth in the accompanying drawings and the description below. Other potential features, aspects, and advantages of the subject matter will become apparent from the description, the drawings, and the claim.

### BRIEF DESCRIPTION OF THE DRAWINGS

FIG. 1 is a diagram illustrating an example compound semiconductor solar cell.

FIG. 2 is a diagram illustrating example graphs showing a concentration of aluminum in the junction buffer layer in FIG. 1.

FIG. 3 is a diagram illustrating example band gaps of a compound semiconductor solar cell that does not include a junction buffer layer.

FIG. 4 is a diagram illustrating example band gaps of a compound semiconductor solar cell that includes a junction buffer layer.

FIG. 5 is a diagram illustrating example graphs showing open-circuit voltages and efficiencies of compound semiconductor solar cells.

FIG. 6 is a diagram illustrating another example compound semiconductor solar cell.

FIG. 7 is a diagram illustrating another example compound semiconductor solar cell.

### DETAILED DESCRIPTION

Reference will now be made in detail to implementations of the invention examples of which are illustrated in the accompanying drawings. Since the invention may be modified in various ways and may have various forms, specific implementations are illustrated in the drawings and are described in detail in the specification. However, it should be understood that the invention are not limited to specific disclosed implementations, but include all modifications, equivalents and substitutes included within the spirit and technical scope of the invention.

The terms ‘first’, ‘second’, etc., may be used to describe various components, but the components are not limited by such terms. The terms are used only for the purpose of distinguishing one component from other components.

For example, a first component may be designated as a second component without departing from the scope of the implementations of the invention. In the same manner, the second component may be designated as the first component.

The term “and/or” encompasses both combinations of the plurality of related items disclosed and any item from among the plurality of related items disclosed.

When an arbitrary component is described as “being connected to” or “being linked to” another component, this should be understood to mean that still another component(s) may exist between them, although the arbitrary component may be directly connected to, or linked to, the second component.

On the other hand, when an arbitrary component is described as “being directly connected to” or “being directly linked to” another component, this should be understood to mean that no other component exists between them.

The terms used in this application are used to describe only specific implementations or examples, and are not intended to limit the invention. A singular expression can include a plural expression as long as it does not have an apparently different meaning in context.

In this application, the terms “include” and “have” should be understood to be intended to designate that illustrated features, numbers, steps, operations, components, parts or combinations thereof exist and not to preclude the existence of one or more different features, numbers, steps, operations, components, parts or combinations thereof, or the possibility of the addition thereof.

In the drawings, the thickness of layers, films, panels, regions, etc., are exaggerated for clarity. It will be understood that when an element such as a layer, film, region, or substrate is referred to as being “on” another element, it can be directly on the other element or intervening elements may also be present. In contrast, when an element is referred to as being “directly on” another element, there are no intervening elements present.

Unless otherwise specified, all of the terms which are used herein, including the technical or scientific terms, have the same meanings as those that are generally understood by a person having ordinary knowledge in the art to which the invention pertains.

The terms defined in a generally used dictionary must be understood to have meanings identical to those used in the context of a related art, and are not to be construed to have ideal or excessively formal meanings unless they are obviously specified in this application.

The following example implementations of the invention are provided to those skilled in the art in order to describe the invention more completely. Accordingly, shapes and sizes of elements shown in the drawings may be exaggerated for clarity.

Hereinafter, a compound semiconductor solar cell according to the present invention will be described with reference to the accompanying drawings.

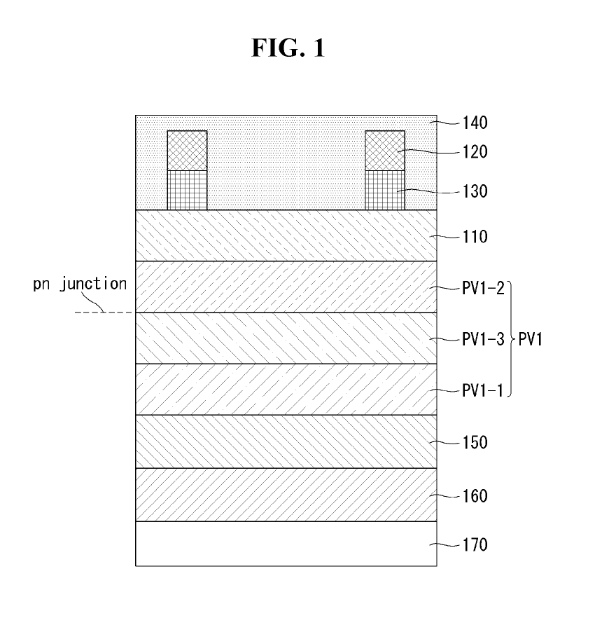

FIG. 1 illustrates an example compound semiconductor solar cell. In some implementations, the compound semiconductor solar cell includes a first light absorption layer PV1, a first window layer 110 positioned on a light incident surface (that is, a front surface) of the first light absorption layer PV1, a first electrode layer 120 positioned on a front surface of the first window layer 110, a first contact layer 130 positioned between the first window layer 110 and the first electrode 120, an anti-reflection layer 140 positioned on the first window layer 110, a first back surface field layer 150 positioned on a rear surface of the first light absorbing layer PV1, a second contact layer 160 positioned on a rear surface of the first back surface field layer 150, and a second electrode 170 positioned on a rear surface of the second contact layer 160.

In some implementations, the compound semiconductor solar cell does not include at least one of first window layer 110, the first contact layer 130, the anti-reflection layer 140, the first back surface field layer 150, and the second contact layer 160. In some other implementations, the compound semiconductor solar cell can include any suitable layer in addition to the elements described above.

In the example, the first light absorbing layer PV1 includes gallium indium phosphide (hereinafter referred to as “GaInP”) based compound which is one of III-VI group semiconductor compounds.

In some implementations, gallium indium phosphide (GaInP) based compound semiconductor solar cells can achieve higher efficiency than gallium arsenide (GaAs) based compound semiconductor solar cells at low illuminance and room temperature. Therefore, in circumstances having low illuminance and a room temperature, the gallium indium phosphide (GaInP) based compound semiconductor solar cell can be superior to the gallium arsenide (GaAs) based compound semiconductor solar cell in usability.

The first light absorbing layer PV1 includes a first semiconductor layer PV1-1 doped with an impurity of a first conductivity type and having a band gap smaller than that of a second semiconductor layer PV1-2, the second semiconductor layer PV1-2 doped with an impurity of a second conductivity type and having a band gap larger than that of the first semiconductor layer PV1-1, a junction buffer layer PV1-3 positioned between the first semiconductor layer PV1-1 and the second semiconductor layer PV1-2 and having a material gradient from the first semiconductor layer PV1-1 to the second semiconductor layer PV1-2.

In some implementations, the first semiconductor layer PV1-1 can be doped with an impurity of n-type and the second semiconductor layer PV1-2 can be doped with an impurity of p-type. In some implementations, the first semiconductor layer PV1-1 can be doped with an impurity of p-type and the second semiconductor layer PV1-2 can be doped with an impurity of n-type. However, the first semiconductor layer PV1-1 and the second semiconductor layer PV1-2 can be doped with impurities of any type and not limited to the types described above.

In the example, the junction buffer layer PV1-3 includes a single layer. The single layer directly contacts the first semiconductor layer PV1-1 and the second semiconductor layer PV1-2. For example, a first surface of the junction buffer layer PV1-2 directly contacts the first semiconductor layer PV1-1 and a second surface of the junction buffer layer PV1-2 directly contacts the second semiconductor layer PV1-2.

In some implementations, the junction buffer layer PV1-3 may have the same conductive type as the first semiconductor layer PV1-1. For example, when the first semiconductor layer PV1-1 and the junction buffer layer PV1-3 are formed as the p-type, the second semiconductor layer PV1-2 is formed as the n-type. As another example, when the first semiconductor layer PV1-1 and the junction buffer layer PV1-3 are formed as the n-type, the second semiconductor layer PV1-2 is formed as the p-type.

The p-type impurity to be doped into at least one of the first semiconductor layer PV1-1, the second semiconductor layer PV1-2 and the junction buffer layer PV1-3 may be carbon, magnesium, zinc, or combinations thereof. And the n-type impurity doped into the remaining layers may be selected from silicon, selenium, tellurium, or combinations thereof.

In this implementation, the first semiconductor layer PV1-1 includes gallium indium phosphide (GaInP) containing an n-type impurity, and is positioned in a region adjacent to the second electrode 170 under the second semiconductor layer PV1-2.

In this example, the composition of the first semiconductor layer PV1-1 may contain 24 to 25 atomic % of gallium (Ga), 25 to 26 atomic % of indium (In) and 50 atomic % of phosphorus (P), and may be formed to a thickness of 100 to 2000 nm.

The first semiconductor layer PV1-1 may be doped with the n-type impurity at a doping concentration of 1×10¹⁵ atom/cm³ to 1×10¹⁸ atom/cm³.

The second semiconductor layer PV1-2 includes the p-type impurity and includes a compound having a larger band gap than that of the first semiconductor layer PV1-1. For example, the second semiconductor layer PV1-2 may be formed of aluminum gallium indium phosphide (AlGaInP). And the second semiconductor layer PV1-2 is positioned in the region adjacent to the first electrode 120.

In this example, the second semiconductor layer PV1-2 may contain 1 to 25 atomic % of aluminum (Al), 1 to 25 atomic % of gallium (Ga), 25 to 26 atomic % of indium (In) and 50 atomic % of phosphide, and may be formed to a thickness of 10 to 1000 nm.

In the second semiconductor layer PV1-2, the p-type impurity is doped at a doping concentration the same as the n-type impurity doping concentration of the first semiconductor layer PV1-1 within a range of 1×10¹⁷ atom/cm³ to 1×10¹⁹ atom/cm³ or the p-type impurity may be doped at a doping concentration higher than the n-type impurity doping concentration of the first semiconductor layer PV1-1 within the above range.

In some implementations, the second semiconductor layer includes a single layer.

The junction buffer layer PV1-3 positioned between the first semiconductor layer PV1-1 and the second semiconductor layer PV1-2 has the same conductivity (that is, the n-type impurity) as the first semiconductor layer PV1-1.

The junction buffer layer PV1-3 includes one or more materials, where a respective concentration of each material changes from a first surface positioned on the first semiconductor layer PV1-1 to a second surface positioned on the second semiconductor layer PV1-2. In some implementations, a concentrations of the materials can change gradually. For example, a concentration of a first material in the junction buffer layer PV1-3 is high near the first surface and becomes gradually lower near the second surface. As another example, a concentration of a second material in the junction buffer layer PV1-3 is low near the first surface and becomes gradually higher near the second surface.

In some implementations, in the junction buffer layer PV1-3, the concentration of aluminum (Al) on or near the second surface is larger than a concentration of aluminum on or near the first surface. In some implementations, a concentration of gallium (Ga) on or near the second surface is smaller than a concentration of gallium on or near the first surface.

Therefore, in the junction buffer layer PV1-3, the junction buffer layer PV1-3 includes the same composition (GaInP) as that of the first semiconductor layer PV1-1 in the portion in contact with the first semiconductor layer PV1-1, and includes the same composition (AlGaInP) as that of the second semiconductor layer PV1-2 in a portion in contact with the second semiconductor layer PV1-2.

In this example, in the junction buffer layer PV1-3, the sum of the concentration of aluminum and the concentration of gallium can be maintained at 24 to 25 atomic %.

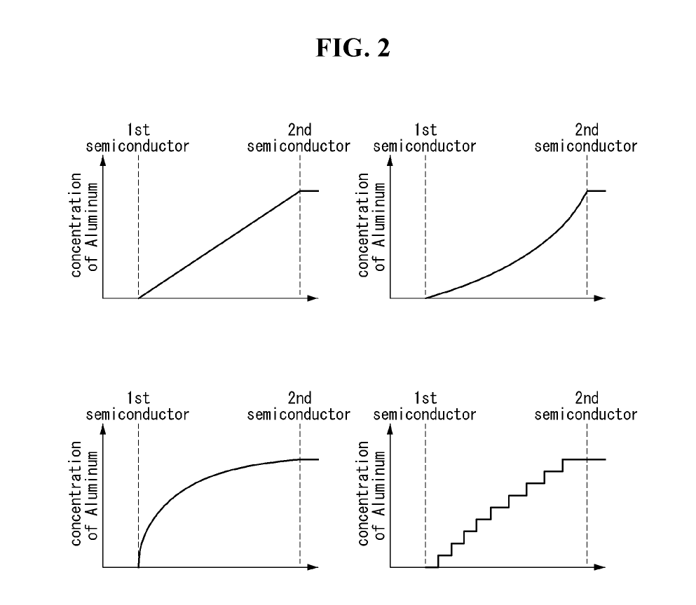

FIG. 2 illustrates example graphs showing a concentration of aluminum in the junction buffer layer in FIG. 1. In some implementations, a concentration of aluminum may increase linearly from the surface in contact with the first semiconductor layer PV1-1 to the surface in contact with the second semiconductor layer PV1-2. In some implementations, a concentration of aluminum may increase non-linearly from the first surface in contact with the first semiconductor layer PV1-1 to the second surface in contact with the second semiconductor layer PV1-2. For example a concentration of aluminum can increase exponentially, logarithmically or stepwise from the first surface to the second surface.

In some implementations, a concentration of gallium can be reduced at the same rate as a concentration of aluminum increases from the surface in contact with the first semiconductor layer to the surface in contact with the second semiconductor layer. In some other implementations, a concentration of gallium can be reduced at a first rate and a concentration of aluminum can increase at a second rate from the first surface to the second surface. The first rate can be set different from the second rate.

In some implementations, concentration of gallium can be reduced linearly from the surface in contact with the first semiconductor layer PV1-1 to the surface in contact with the second semiconductor layer PV1-2. In some other implementations, a concentration of gallium can be reduced non-linearly from the surface in contact with the first semiconductor layer PV1-1 to the surface in contact with the second semiconductor layer PV1-2.

The junction buffer layer PV1-3 may have a thickness of 10 to 300 nm. When the p-type impurity doping concentration of the second semiconductor layer PV1-2 and the n-type impurity doping concentration of the first semiconductor layer PV1-1 are equal to each other, the n-type impurity doping concentration of the junction buffer layer PV1-3, the doping concentration of the n-type impurity of the first semiconductor layer PV1-1 and the doping concentration of the p-type impurity of the second semiconductor layer PV1-2 may be the same.

In some implementations, when the p-type impurity doping concentration of the second semiconductor layer PV1-2 is higher than the n-type impurity doping concentration of the first semiconductor layer PV1-1, the n-type or p-type impurity doping concentration of the junction buffer layer PV1-3 is more than the n-type impurity doping concentration of the first semiconductor layer PV1-1 and is less than the p-type impurity doping concentration of the second semiconductor layer PV1-2.

In these implementations, the n-type impurity doping concentration of the junction buffer layer PV1-3 may be constant in the thickness direction of the junction buffer layer PV1-3 or may increase linearly or nonlinearly from the first semiconductor layer PV1-1 toward the second semiconductor layer PV1-2.

Since the first semiconductor layer PV1-1 and the second semiconductor layer PV1-2 are formed of different materials having different band gaps, the junction buffer layer PV1-3 is positioned between the first semiconductor layer PV1-1 and the second semiconductor layer PV1-2 and the junction buffer layer PV1-3 is formed in the same conductive type as the first semiconductor layer PV1-1, the junction buffer layer PV1-3 and the second semiconductor layer PV1-2 form a p-n junction, and a hetero junction is formed inside the junction buffer layer PV1-3.

As described above, due to the junction buffer layer PV1-3, the p-n junction and the heterojunction of the first light absorbing layer PV1-1 are offset from each other.

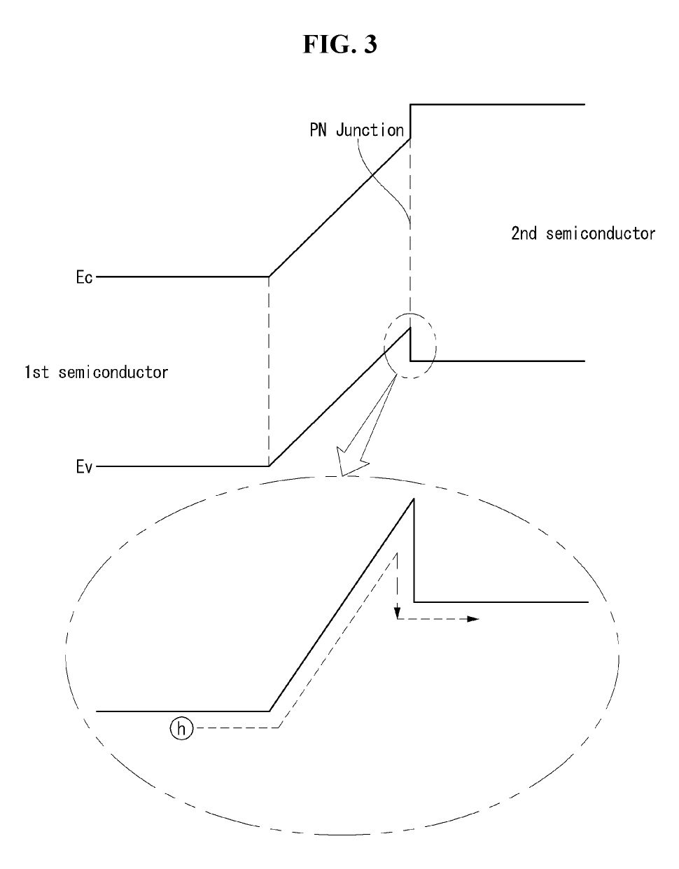

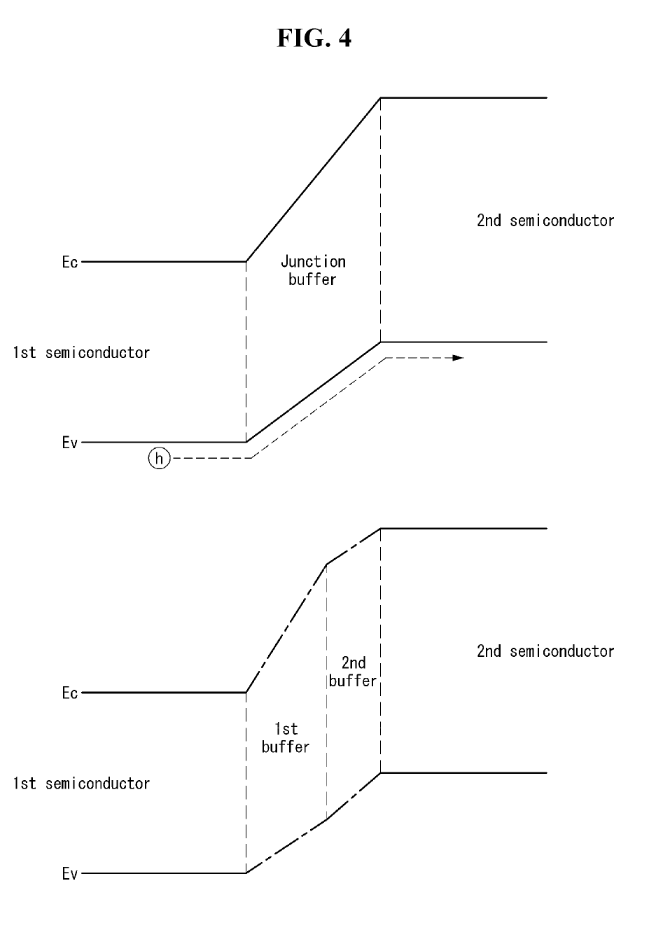

FIG. 3 illustrates example band gaps of a compound semiconductor solar cell where the solar cell does not include a junction buffer layer. FIG. 4 illustrates example band gaps of a compound semiconductor solar cell where the solar cell includes a junction buffer layer.

In FIG. 3, where the solar cell does not include a junction buffer layer, the solar cell can have a band spike. The bank spike interferes the movement of the hole at the p-n junction.

In FIG. 4, where the solar cell includes a junction buffer layer, a bank spike can be reduced or eliminated by having the junction buffer layer between the first semiconductor layer and the second semiconductor layer.

Thus, the electron-hole pairs generated by the light incident through the light incident surface of the first light absorbing layer PV1 are electrically coupled to each other by the internal potential difference formed by the p-n junction of the first light absorbing layer PV1. Electrons move to the n-type, and holes move to the p-type.

The electrons generated in the first light absorbing layer PV1 move to the second electrode 170 through the first back surface field layer 150 and the second contact layer 160, and the holes generated in the first light absorbing layer PV1 move to the first electrode 120 through the first window layer 110 and the first contact layer 130.

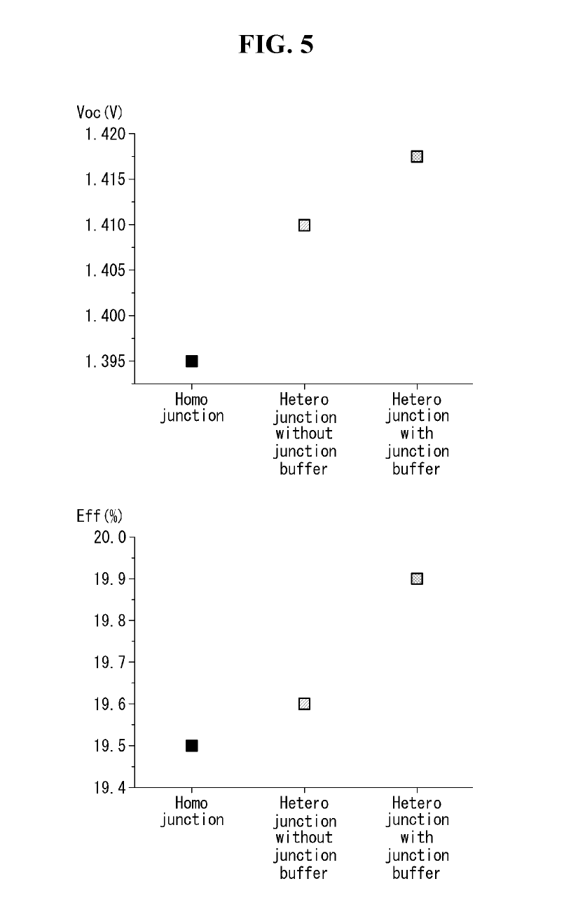

FIG. 5 illustrates example graphs showing open-circuit voltages and efficiencies of compound semiconductor solar cells. In particular, the top graph in FIG. 5 shows open-circuit voltages for a compound semiconductor solar cell having a homo-junction, a compound semiconductor solar cell having a hetero junction without a junction buffer, and a compound semiconductor solar cell having a hetero junction with a junction buffer. The bottom graph in FIG. 5 shows efficiencies for a compound semiconductor solar cell having a homo-junction, a compound semiconductor solar cell having a hetero junction without a junction buffer, and a compound semiconductor solar cell having a hetero junction with a junction buffer. In this example, the solar cell including the junction buffer can be the solar cell described with reference to FIG. 1.

In FIG. 5, the open-circuit voltage and the efficiency of a compound semiconductor solar cell that does not include a junction buffer layer are higher than the open-circuit voltage and the efficiency of a compound semiconductor solar cell having a homojunction. The open-circuit voltage and the efficiency of a compound semiconductor solar cell that include a hetero junction without a junction buffer layer are lower than the open-circuit voltage and the efficiency of a compound semiconductor solar cell that include a hetero junction with a junction buffer layer.

In some implementations, the junction buffer layer includes a double layer. Each of the double layer can be a first buffer and a second buffer. In these implementations, a concentration of a material in the first buffer changes, e.g., gradually changes, from one surface of the first buffer to another surface of the first buffer and a concentration of a material in the second buffer is constant from one surface of the second buffer to another surface of the second buffer.

In some implementations, a concentration of a material in the first buffer changes, e.g., gradually changes, from one surface of the first buffer to another surface of the first buffer and a concentration of a material in the second buffer also changes, e.g., gradually changes, from one surface of the second buffer to another surface of the second buffer. For example, referring back to the bottom graph in FIG. 4, the change rate of the concentration of the material in the first buffer is higher than the change rate of the concentration of the material in the second buffer. The lower change rate of the concentration of the material in the second buffer represents that the E-field for moving the holes to the emitter region, i.e., the second semiconductor layer, is reduced. Thus, when extracting holes into the emitter region, a junction buffer layer with a single layer, where a concentration of a material in the junction buffer layer changes, e.g., gradually changes, improves an open-circuit voltage by achieving a high open-circuit voltage comparing to a junction buffer layer with a double layer, where a concentration of a material in the junction buffer layer changes only in a first buffer of the double layer and a concentration of a material in the junction buffer layer does not change in a second buffer of the double layer. In some implementations, the change rates can have any suitable values for various implementation and not limited to the example described with reference to FIG. 4.

Referring back to FIG. 1, in some implementations, the light absorbing layer PV1 may be formed on a substrate by a metal organic chemical vapor deposition (MOCVD) method, a molecular beam epitaxy (MBE) method, or any other suitable method for forming an epitaxial layer.

The substrate may serve as a base providing a suitable lattice structure in which a light absorbing layer PV is formed, and may be formed of a group III-V compound containing gallium arsenide (GaAs).

The substrate may be a substrate that was previously used to fabricate one or more compound semiconductor solar cells.

That is, the substrate can be separated from the compound semiconductor solar cell at several points in the manufacturing process, and can be reused for manufacturing other compound semiconductor solar cells.

The first window layer 110 may be formed between the first light absorbing layer PV1 and the first electrode 120 and may be formed of III-VI group semiconductor compound containing the same conductive type as that of the second semiconductor layer PV1-2, and may contain the p-type impurity at a higher concentration than the second semiconductor layer PV1-2. In this example, the first window layer 110 may act as a front surface field blocking electrons. However, the first window layer 110 may not contain the p-type impurity.

The first window layer 110 serves to passivate the front surface of the first light absorbing layer PV1. Therefore, when the carrier (electrons or holes) moves to the light incident surface of the light absorbing layer PV1, the first window layer 110 can prevent the carriers (holes) from recombining on the light incident surface of the first light absorbing layer PV1.

Since the first window layer 110 is disposed on the front surface (i.e., light incident surface) of the first light absorbing layer PV1, in order to prevent light incident on the first light absorbing layer PV1 from being absorbed, the first window layer 110 may have an energy band gap higher than the energy band gap of the first light absorbing layer PV1. For example, the first window layer 110 may be formed of aluminum indium phosphide (AlInP) or aluminum gallium indium phosphide (AlGaInP).

In some implementations, the anti-reflection layer 140 can cover at least one portion of the surface of the first window layer 110. In some implementations, the anti-reflection layer 140 can cover the entire surface of the first window layer 110 except the regions at which the first electrode 120 and/or the first contact layer 130 are located.

In some implementations, the anti-reflection layer 140 may be disposed on the first contact layer 130 and the first electrode 120 as well as the exposed first window layer 110. In this example, the compound semiconductor solar cell may further include at least one bus bar electrodes physically connecting the plurality of first electrodes 120, and the bus bar electrode may not be covered by the anti-reflection layer 140 and can be exposed to the outside.

The anti-reflection layer 140 having such a structure may include magnesium fluoride, zinc sulfide, titanium oxide, silicon oxide, derivatives thereof, or a combination thereof.

The first electrode 120 may be formed to extend in the first direction X-X′, and the plurality of the first electrodes 120 may be spaced apart from each other along a second direction Y-Y′ orthogonal to the first direction.

The first electrode 120 may be formed to include an electrically conductive material. For example, the first electrode 120 may include at least one of gold (Au), germanium (Ge), and nickel (Ni).

The first contact layer 130 positioned between the first window layer 110 and the first electrode 120 is formed by doping the p-type impurity with a dopant concentration higher than the impurity doping concentration of the first window layer 110 into the III-V compound semiconductor, such as gallium arsenide (GaAs) and aluminum gallium arsenide (AlGaAs).

The first contact layer 130 forms an ohmic contact between the first window layer 110 and the first electrode 120. That is, when the first electrode 120 directly contacts the first window layer 110, the ohmic contact between the first electrode 120 and the first light absorbing layer PV1 is not well formed because the impurity doping concentration of the first window layer 110 is low. Therefore, the carrier moved to the first window layer 110 can be interrupted to move to the first electrode 120 or can be destroyed.

However, when the first contact layer 150 is formed between the first electrode 120 and the first window layer 110, since the first contact layer 150 forms an ohmic contact with the first electrode 120, the carrier is smoothly moved and the short circuit current density Jsc of the compound semiconductor solar cell increases. Thus, the efficiency of the solar cell can be further improved.

In order to form an ohmic contact with the first electrode 120, the doping concentration of the p-type impurity doped in the first contact layer 130 may be greater than the doping concentration of the p-type impurity doped in the first window layer 110.

The first contact layer 130 is formed in the same shape as the first electrode 120.

The first back surface field layer 150 positioned on the rear surface of the first semiconductor layer PV1-1 has the same conductive type as the first semiconductor layer PV1-1 directly contacting the first back surface field layer 150. Accordingly, the back surface field layer 150 is the n-type and includes the same material as the first window layer 110. That is, the back surface field layer 150 includes aluminum indium phosphide (AlInP).

The first back surface field layer 150 having such a configuration acts to block holes.

The second contact layer 160 positioned on the rear surface of the first back surface field layer 150 is positioned on the entire rear surface of the first back surface field layer and is formed by doping the n-type impurity into the III-VI group semiconductor compound such as gallium arsenide (GaAs) or aluminum gallium arsenide (AlGaAs) at a higher doping concentration than the first semiconductor layer PV 1-1.

The second contact layer 160 can form an ohmic contact with the second electrode 170, so that the short circuit current density Jsc of the compound semiconductor solar cell can be further improved. Thus, the efficiency of the solar cell can be further improved.

The second electrode 170 positioned on the rear surface of the second contact layer 160 may have a shape of a sheet positioned entirely on the rear surface of the first light absorbing layer PV1.

In this example, the second electrode 170 may has the same planar area as the first light absorbing layer PV 1.

A compound semiconductor solar cell having a first light absorbing layer based on gallium indium phosphide (GaInP) can be formed by an epitaxial lift-off (ELO) method, specifically, epitaxially growing a sacrificial layer on a substrate, epitaxially growing a first contact layer on the sacrificial layer, epitaxially growing the first light absorbing layer on the first contact layer, epitaxially growing the first back surface field layer on the first light absorbing layer, epitaxially growing the second contact layer on the first back surface field layer, forming the second electrode on the second contact layer, removing the sacrificial layer by an epitaxial lift-off process, and patterning the first contact layer and forming a first electrode.

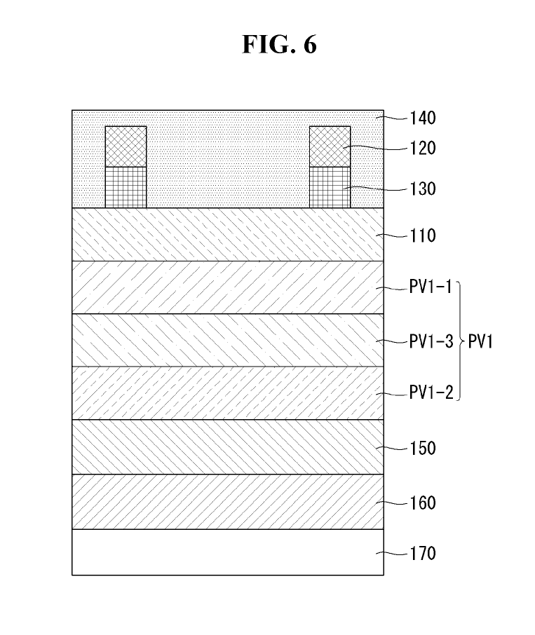

FIG. 6 illustrates another example compound semiconductor solar cell. The compound semiconductor solar cell in FIG. 6 is similar to the compound semiconductor solar cell described with reference to FIG. 1 except the differences described below. However, the differences are only examples and any suitable changes or modifications can be made for various implementations.

Comparing to the compound semiconductor solar cell in FIG. 1, where the first semiconductor layer PV1-1 is positioned in a region adjacent to the second electrode 170, and the second semiconductor layer PV1-2 is positioned in a region adjacent to the first electrode 120, the compound semiconductor solar cell in FIG. 6 includes the first semiconductor layer PV1-1 that is positioned in the region adjacent to the first electrode 120 and the second semiconductor layer PV1-2 that is positioned in the region adjacent to the second electrode 170.

As described above, the compound semiconductor solar cell of this implementation is formed opposite to the implementation of FIG. 1 described above in the stacking position or order of the first semiconductor layer (PV 1-1) and the second semiconductor layer (PV 1-1). In some implementations, the conductive type of the layer of the compound semiconductor solar cell to be changed can be different from the compound semiconductor solar cell in FIG. 1. The conductive type can be determined based on the conductive type of the first and second semiconductor layers.

As described above, the stacking positions or order of the first semiconductor layer and the second semiconductor layer in the laminated structure of the compound semiconductor solar cell can be changed.

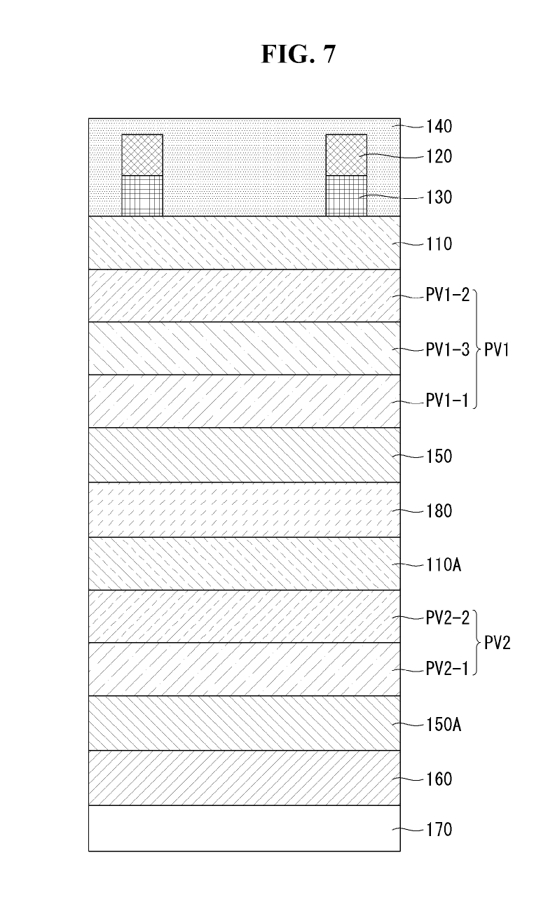

FIG. 7 illustrates another example compound semiconductor solar cell. The compound semiconductor solar cell in FIG. 7 is similar to the compound semiconductor solar cell described with reference to FIG. 1 except the differences described below. However, the differences are only examples and any suitable changes or modifications can be made for various implementations.

The compound semiconductor solar cell in FIG. 7 comprises a GaAs-based second light absorbing layer PV 2 under the GaInP-based first light absorbing layer PV 1-1, e.g., the first light absorbing layer shown in FIG. 1 or FIG. 6. In detail, a GaAs-based second light absorbing layer PV2 is disposed between the first back surface field layer 150 and the second contact layer 160.

Since the second light absorbing layer PV2 includes a GaAs-based compound, light in a first wavelength band, e.g., a short wavelength band, is absorbed in the first light absorbing layer PV1, and light in a second wavelength band, e.g., a long wavelength band, is absorbed in the second light absorbing layer PV2. By using two layers to absorb lights in two different wavelength bands, the efficiency of the compound semiconductor solar cell is improved.

The second light absorbing layer PV2 includes an n-type or p-type third semiconductor layer PV2-1 and a p-type or n-type fourth semiconductor layer PV2-2, and the third semiconductor layer PV2-1 and the fourth semiconductor layer PV2-2 form a homojunction or a heterojunction.

A tunnel junction layer 180 is positioned between the first back surface field layer 150 and the fourth semiconductor layer PV2-2, and the tunnel junction layer 180 electrically connects the first semiconductor layer PV1-1 of the first light absorbing layer PV1 to the fourth semiconductor layer PV2-2 of the second light absorbing layer PV2.

A second window layer 110A is positioned between the tunnel junction layer 180 and the fourth semiconductor layer PV2-2, and a second back surface field layer 150a is positioned on a rear surface of the third semiconductor layer PV2-1.

The second window layer 110A may contain a p-type or n-type impurity at a higher concentration than the fourth semiconductor layer PV2-2 directly contacting the second window layer 110A. In this example, the second window layer 110A can act as a front surface field layer blocking carriers (electrons or holes).

The second back surface field layer 150A directly contacts the second contact layer 160 and the third semiconductor layer PV2-1 and has the same conductive type as the third semiconductor layer PV2-1.

What is claimed is:

1. A compound semiconductor solar cell, comprising:
a first light absorbing layer that includes gallium indium phosphide (GaInP);
a first electrode positioned on a first surface of the first light absorbing layer; and
a second electrode positioned on a second surface of the first light absorbing layer,
wherein the first light absorbing layer includes;
a first semiconductor layer that includes GaInP, that is doped as a first conductive type, and that has a first band gap,
a second semiconductor layer that includes aluminum gallium indium phosphide (AlGaInP), that is doped as a second conductive type, that has a second band gap that is larger than the first band gap, and that forms a hetero junction with the first semiconductor layer, and
a junction buffer layer positioned between the first semiconductor layer and the second semiconductor layer and that includes a first material comprising aluminum and a second material comprising gallium,
and
wherein in the junction buffer layer, a concentration of the first material on a surface in contact with the second semiconductor layer is larger than the concentration of the first material on a surface in contact with the first semiconductor layer, and a concentration of the second material on the surface in contact with the second semiconductor layer is smaller than the concentration of the second material on the surface in contact with the first semiconductor layer.

2. The compound semiconductor solar cell of claim 1, wherein a sum of a concentration of the first material in the junction buffer layer and a concentration of the second material in the junction buffer layer is between 24 and 25 atomic %.

3. The compound semiconductor solar cell of claim 2, wherein a concentration of the first material in the junction buffer layer and a concentration of the second material in the junction buffer layer are changed linearly, nonlinearly, exponentially,
logarithmically or stepwise between a first surface of the junction buffer layer positioned on the first semiconductor layer and a second surface of the junction buffer layer positioned on the second semiconductor layer.

4. The compound semiconductor solar cell of claim 2, wherein a concentration of gallium in the first semiconductor layer is between 24 and 25 atomic %, a concentration of indium in the first semiconductor layer is between 25 and 26 atomic %, and a concentration of phosphide in the first semiconductor layer is 50 atomic %, and
wherein a concentration of aluminum in the second semiconductor layer is between 1 and 25 atomic %, a concentration of gallium in the second semiconductor layer is between 1 and 25 atomic %, a concentration of indium in the second semiconductor layer is between 25 and 26 atomic %, and a concentration of phosphide in the second semiconductor layer is 50 atomic %.

5. The compound semiconductor solar cell of claim 1, wherein a thickness of the first semiconductor layer is between 100 and 2000 nm, a thickness of the second semiconductor layer is between 10 and 1000 nm, and a thickness of the junction buffer layer is between 10 and 300 nm.

6. The compound semiconductor solar cell of claim 5, wherein the junction buffer layer is doped as the first conductive type, and
wherein (i) the first conductive type is a p-type and the second conductive type is an n-type or (ii) the first conductive type is an n-type and the second conductive type is a p-type.

7. The compound semiconductor solar cell of claim 5, wherein the junction buffer layer is doped as the first conductive type, and
wherein a doping concentration of the junction buffer layer is (i) larger than a doping concentration of the first semiconductor layer and (ii) smaller than a doping concentration of the second semiconductor layer.

8. The compound semiconductor solar cell of claim 7, wherein a doping concentration of the junction buffer layer is even from a first surface of the junction buffer layer positioned on the first semiconductor layer to a second surface of the junction buffer layer positioned on the second semiconductor layer, and
wherein a doping concentration of the junction buffer layer increases from the first surface of the junction buffer layer to the second surface of the junction buffer layer.

9. The compound semiconductor solar cell of claim 1, further comprising:
a first window layer positioned on the first surface of the first light absorbing layer;
a first contact layer positioned between the first window layer and the first electrode;
an anti-reflection film that covers at least a portion of the first window layer;
a first back surface field layer positioned on the second surface of the first light absorbing layer; and
a second contact layer positioned between the first back surface field layer and the second electrode.

10. The compound semiconductor solar cell of claim 9, wherein (i) the first window layer directly contacts at least a portion of the first semiconductor layer and the first back surface field layer directly contacts at least a portion of the second semiconductor layer or (ii) the first window layer directly contacts at least a portion of the second semiconductor layer and the first back surface field layer directly contacts at least a portion of the first semiconductor layer, and
wherein the first window layer and the first back surface field layer include aluminum indium phosphide (AlInP).

11. The compound semiconductor solar cell of claim 10, wherein the first back surface field layer directly contacts the second semiconductor layer, and
wherein the first back surface field layer is doped as the second type.

12. The compound semiconductor solar cell of claim 10, wherein the first back surface field layer directly contacts the first semiconductor layer, and
wherein the first back surface field layer is doped as the first type.

13. The compound semiconductor solar cell of claim 10, further comprising:
a second light absorbing layer that includes gallium arsenide (GaAs) and positioned between the first back surface field layer and the second contact layer.

14. The compound semiconductor solar cell of claim 13, wherein the second light absorbing layer includes:
a third semiconductor layer that is doped as the first type, and
a fourth semiconductor layer that is doped as the second type.

15. The compound semiconductor solar cell of claim 14, wherein the third semiconductor layer and the fourth semiconductor layer form a homojunction or a heterojunction.

16. The compound semiconductor solar cell of claim 15, further comprising:
a tunnel junction layer positioned between the first back surface field layer and the second light absorbing layer.

17. The compound semiconductor solar cell of claim 16, further comprising,
a second window layer positioned between the tunnel junction layer and the second light absorbing layer; and
a second back surface field layer positioned on a surface of the second light absorbing layer,
wherein the second back surface field layer directly contacts the second contact layer.

18. The compound semiconductor solar cell of claim 17, wherein the second back surface field layer directly contacts the third semiconductor layer and is doped as the first conductive type, or
wherein the second back surface field layer directly contacts the fourth semiconductor layer and is doped as the second conductive type.

19. The compound semiconductor solar cell of claim 1, wherein the first surface of the first light absorbing layer is a surface on which light is incident, and
wherein the second surface of the first light absorbing layer is different from the first surface of the first light absorbing layer.

20. The compound semiconductor solar cell of claim 1, wherein the first conductive type is an n-type and the second conductive type is a p-type, or
wherein the first type is a p-type and the second type is an n-type.
